(19) United States
(12) Patent Application Publication
(10) Pub. No.: US 2022/0359242 A1
(43) Pub. Date: Nov. 10, 2022

(54) TEMPERATURE CONTROL SYSTEM AND TEMPERATURE CONTROL METHOD

(71) Applicant: KELK Ltd., 3-25-1, Shimomiya, Hiratsuka-shi (JP)

(72) Inventors: Atsushi KOBAYASHI, Kanagawa (JP); Kazuhiro MIMURA, Kanagawa (JP)

(21) Appl. No.: 17/621,635

(22) PCT Filed: May 28, 2020
(86) PCT No.: PCT/JP2020/021253

§ 371 Date: Dec. 21, 2021

(30) Foreign Application Priority Data
Jul. 2, 2019 (JP) 2019-123539

(51) Int. Cl. H01L 21/67

(52) U.S. Cl. CPC H01L 21/67248; H01L 21/6715

(57) ABSTRACT

A temperature control system includes a circulation channel including a temperature control target to be temperature-controlled via a fluid, a heater capable of heating the fluid, and a cooler capable of cooling the fluid, a bypass channel connected to each of a first portion of the circulation channel located upstream of the cooler and a second portion of the circulation channel located downstream of the cooler to bypass the cooler, a valve device capable of controlling a flow rate of the fluid flowing through the cooler and a flow rate of the fluid flowing through the bypass channel individually, and a control device. The control device includes a valve controller configured to control the valve device to make a temperature of the fluid at the second portion equal to a predetermined temperature.

### FIELD

The present invention relates to a temperature control system and a temperature control method.

### BACKGROUND

In the art related to a semiconductor manufacturing apparatus, a temperature control system as disclosed in Patent Literature 1 is used.

### CITATION LIST

### Patent Literature

Patent Literature 1: JP 2013-105359 A

### SUMMARY

### Technical Problem

A temperature control target is temperature-controlled via a fluid. The fluid fed to the temperature control target is temperature-controlled by a heater and a cooler. There is a demand for a technique capable of reducing energy consumed by the temperature-control of the temperature control target.

It is therefore an object of an aspect of the present invention to reduce energy consumed by temperature-control of a temperature control target.

### Solution to Problem

According to an aspect of the present invention, a temperature control system comprises: a circulation channel including a temperature control target to be temperature-controlled via a fluid, a heater capable of heating the fluid, and a cooler capable of cooling the fluid; a bypass channel connected to a first portion of the circulation channel located upstream of the cooler and a second portion of the circulation channel located downstream of the cooler to bypass the cooler; a valve device capable of controlling a flow rate of the fluid flowing through the cooler and a flow rate of the fluid flowing through the bypass channel individually; and a control device including a valve controller configured to control the valve device to make a temperature of the fluid at the second portion equal to a predetermined temperature.

### Advantageous Effects of Invention

According to the aspect of the present invention, energy consumed by the temperature-control of the temperature control target can be reduced.

### BRIEF DESCRIPTION OF DRAWINGS

FIG. 1 is a diagram illustrating a structure of a temperature control system according to a first embodiment.

FIG. 2 is a block diagram illustrating the temperature control system according to the first embodiment.

FIG. 3 is a flowchart illustrating a temperature control method according to the first embodiment.

FIG. 4 is a diagram illustrating a structure of a temperature control system according to a second embodiment.

FIG. 5 is a flowchart illustrating a temperature control method according to the second embodiment.

### DESCRIPTION OF EMBODIMENTS

Hereinafter, embodiments according to the present invention will be described with reference to the drawings, but the present invention is not limited to the embodiments. Components of the embodiments to be described below may be combined as needed. Further, some of the components may not be used.

### First Embodiment

<Temperature Control System>

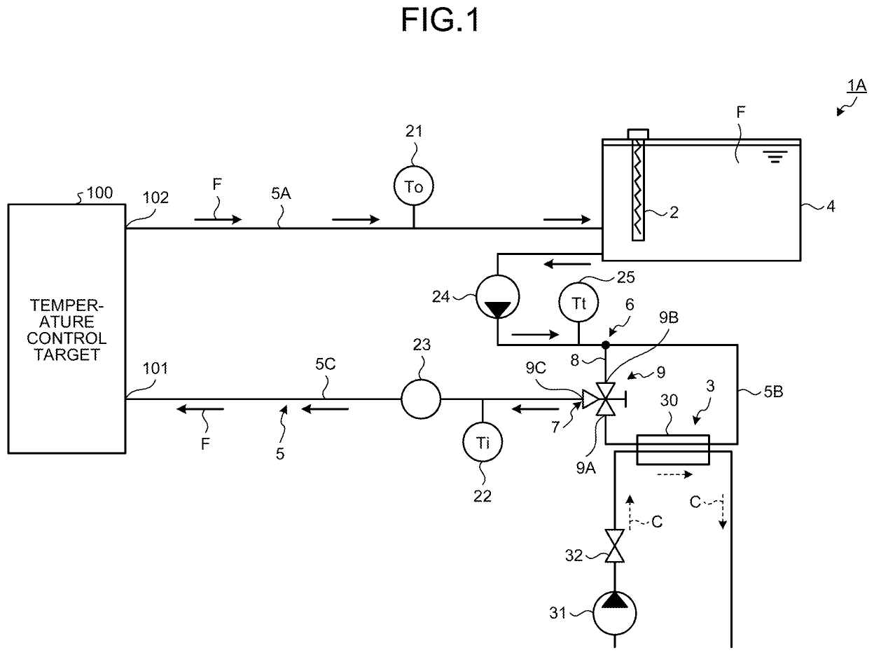

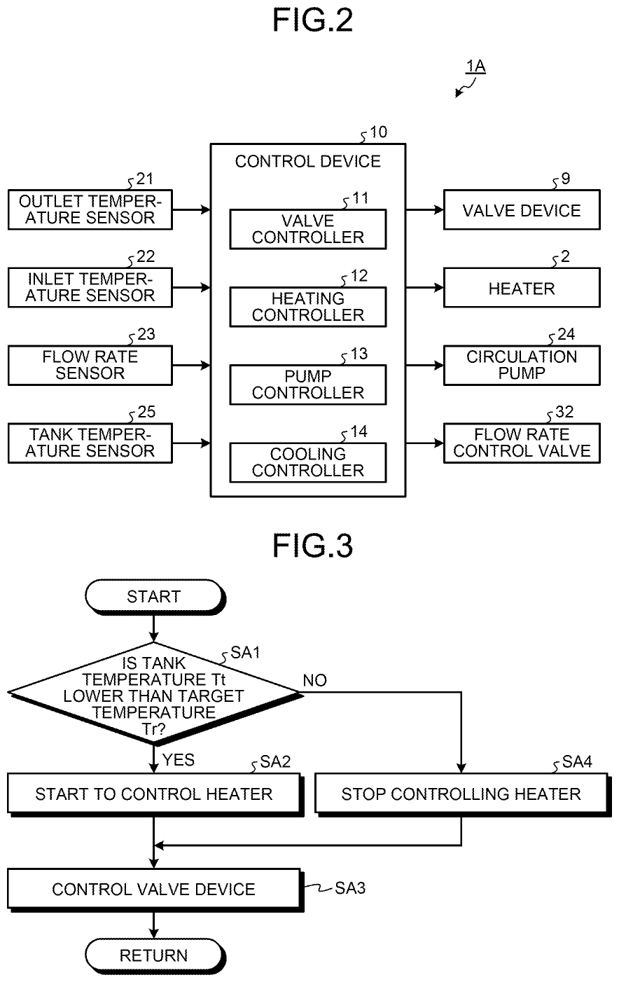

FIG. 1 is a diagram illustrating a structure of a temperature control system 1A according to the present embodiment. FIG. 2 is a block diagram illustrating the temperature control system 1A according to the present embodiment.

The temperature control system 1A temperature-controls a temperature control target 100 via a fluid F. The temperature control system 1A temperature-controls the temperature control target 100 to make the temperature of the temperature control target 100 equal to a target temperature Tr. The temperature control system 1A temperature-controls the temperature control target 100 by feeding, to the temperature control target 100, the fluid F temperature-controlled to be equal in temperature to the target temperature Tr. According to the present embodiment, the fluid F is a liquid. Alternatively, the fluid F may be a gas.

As illustrated in FIGS. 1 and 2, the temperature control system 1A includes a circulation channel 5 including the temperature control target 100 to be temperature-controlled via the fluid F, a heater 2 capable of heating the fluid F, a cooler 3 capable of cooling the fluid F, and a tank 4, a bypass channel 8 connected to a first portion 6 of the circulation channel 5 located upstream of the cooler 3 and a second portion 7 of the circulation channel 5 located downstream of the cooler 3 to bypass the cooler 3, a valve device 9 capable of controlling a flow rate of the fluid F flowing through the cooler 3 and a flow rate of the fluid F flowing through the bypass channel 8 individually, and a control device 10.

The temperature control system 1A further includes an outlet temperature sensor 21 configured to detect an outlet temperature To indicating the temperature of the fluid F flowing out of the temperature control target 100, an inlet temperature sensor 22 configured to detect an inlet temperature Ti indicating the temperature of the fluid F flowing into the temperature control target 100, a tank temperature sensor 25 configured to detect a tank temperature Tt indicating the temperature of the fluid F flowing out of the tank 4, a flow rate sensor 23 configured to detect a flow rate of the fluid F flowing through the circulation channel 5, and a circulation pump 24 configured to be driven to cause the fluid F to circulate through the circulation channel 5.

The temperature control target 100 includes at least a part of the semiconductor manufacturing apparatus. The temperature control target 100 includes, for example, a wafer holder of a plasma treatment apparatus. The wafer holder holds a semiconductor wafer subjected to plasma treatment in the plasma treatment apparatus. The wafer holder is made of, for example, aluminum. The wafer holder includes an electrostatic chuck that holds the semiconductor wafer with an electrostatic attracting force. The electrostatic chuck attracts and holds the semiconductor wafer with Coulomb force generated when a DC voltage is applied. The semiconductor wafer is temperature-controlled through temperature-control of the wafer holder.

The temperature control target 100 has an inlet 101 into which the fluid F flows and an outlet 102 from which the fluid F flows out. The temperature control target 100 is temperature-controlled to be equal in temperature to the target temperature Tr via the fluid F temperature-controlled to be equal in temperature to the target temperature Tr and flowing through the temperature control target 100. The fluid F flowing through the temperature control target 100 flows out from the outlet 102.

The semiconductor manufacturing apparatus has a time during which the temperature control target 100 is heated and a time during which the temperature control target 100 is not heated. When the semiconductor manufacturing apparatus is a plasma treatment apparatus, the time during which the temperature control target 100 is heated is exemplified by a time during which plasma treatment is applied to a semiconductor wafer held by the temperature control target 100. The time during which the temperature control target 100 is not heated is exemplified by a time during which no plasma treatment is applied. The time during which the temperature control target 100 is not heated is exemplified by a loading time during which the semiconductor wafer is loaded into the temperature control target 100 and an unloading time during which the semiconductor wafer is unloaded from the temperature control target 100.

In the following description, the time during which the temperature control target 100 is heated is referred to as a process time as needed, and the time during which the temperature control target 100 is not heated is referred to as an idle time as needed.

During the process time, the temperature control target 100 is heated, and the temperature of the fluid F flowing through the temperature control target 100 increases accordingly. When the temperature of the fluid F flowing into the inlet 101 is equal to the target temperature Tr, the outlet temperature To of the fluid F flowing out from the outlet 102 is equal to a first temperature Top higher than the target temperature Tr during the process time.

During the idle time, the temperature control target 100 is not heated, and the temperature of the fluid F flowing through the temperature control target 100 decreases due to heat dissipation from the temperature control target 100. When the temperature of the fluid F flowing into the inlet 101 is equal to the target temperature Tr, the outlet temperature To of the fluid F flowing out from the outlet 102 is equal to a second temperature Toa lower than the target temperature Tr during the idle time.

As an example, the target temperature Tr is 80° C. The first temperature Top indicating the outlet temperature To during the process time is about 90° C. The second temperature Toa indicating the outlet temperature To during the idle time is about 79° C.

The heater 2 heats the fluid F. When power is supplied, the control of the heater 2 is started. The heater 2 is disposed in the tank 4. The fluid F is stored in the tank 4. The heater 2 heats the fluid F stored in the tank 4.

The cooler 3 cools the fluid F. The fluid F is cooled by flowing through the cooler 3. The cooler 3 includes a heat exchanger 30, a feed pump 31 configured to be driven to feed a cooling fluid C to the heat exchanger 30, and a flow rate control valve 32 configured to control a flow rate of the cooling fluid C to be fed to the heat exchanger 30. The cooling fluid C temperature-controlled to be equal in temperature to a predetermined cooling temperature Tc is fed to the heat exchanger 30. As an example, the cooling temperature Tc is 25° C. The cooler 3 cools the fluid F by transferring heat between the cooling fluid C and the fluid F in the heat exchanger 30.

The circulation channel 5 includes an upstream portion 5A extending between the outlet 102 and the tank 4, a midstream portion 5B extending between the tank 4 and the cooler 3, and a downstream portion 5C extending between the cooler 3 and the inlet 101. The circulation pump 24 is disposed in the midstream portion 5B. When the circulation pump 24 is driven, the fluid F circulates through the circulation channel 5.

The outlet temperature sensor 21 detects the temperature of the fluid F flowing out from the outlet 102. The outlet temperature sensor 21 is provided in the upstream portion 5A of the circulation channel 5. The outlet temperature sensor 21 detects the temperature of the fluid F flowing through the upstream portion 5A. The outlet temperature sensor 21 detects the temperature of the fluid F that has been neither heated by the heater 2 nor cooled by the cooler 3. Detection data of the outlet temperature sensor 21 is output to the control device 10.

The inlet temperature sensor 22 detects the temperature of the fluid F flowing into the inlet 101. The inlet temperature sensor 22 is provided in the downstream portion 5C of the circulation channel 5. The inlet temperature sensor 22 detects the temperature of the fluid F flowing through the downstream portion 5C. The inlet temperature sensor 22 detects the temperature of the fluid F that has been cooled by the cooler 3. When the heater 2 heats the fluid F, the inlet temperature sensor 22 detects the temperature of the fluid F that has been heated by the heater 2 and cooled by the cooler 3. When the heater 2 does not heat the fluid F, the inlet temperature sensor 22 detects the temperature of the fluid F that has been cooled by the cooler 3. Detection data of the inlet temperature sensor 22 is output to the control device 10.

The tank temperature sensor 25 detects the temperature of the fluid F flowing out of the temperature control target 100 and flowing out of the tank 4. The tank temperature sensor 25 is provided in the midstream portion 5B of the circulation channel 5 extending between the tank 4 and the first portion 6. In the example illustrated in FIG. 1, the tank temperature sensor 25 is disposed between the circulation pump 24 and the first portion 6. Note that the tank temperature sensor 25 may be disposed between the tank 4 and circulation pump 24. The tank temperature sensor 25 detects the temperature of the fluid F flowing through the midstream portion 5B. The tank temperature sensor 25 detects the temperature of the fluid F that has been heated by the heater 2, but has not yet been cooled by the cooler 3. Detection data of the tank temperature sensor 25 is output to the control device 10.

The flow rate sensor 23 detects the flow rate of the fluid F flowing through the circulation channel 5. The flow rate sensor 23 is provided in the downstream portion 5C of the circulation channel 5. The flow rate sensor 23 is disposed in the downstream portion 5C between the inlet temperature sensor 22 and the inlet 101. The flow rate sensor 23 detects the flow rate of the fluid F flowing through the downstream portion 5C. Detection data of the flow rate sensor 23 is output to the control device 10.

The bypass channel 8 is provided to bypass the cooler 3. The bypass channel 8 is provided to connect the first portion 6 of the circulation channel 5 and the second portion 7 of the circulation channel 5. The first portion 6 is defined in the midstream portion 5B of the circulation channel 5. The second portion 7 is defined in the downstream portion 5C of the circulation channel 5.

According to the present embodiment, the first portion 6 is defined in the midstream portion 5B between the circulation pump 24 and the cooler 3. The second portion 7 is defined in the downstream portion 5C between the cooler 3 and the inlet temperature sensor 22.

The valve device 9 controls the flow rate of the fluid F flowing through the cooler 3 and the flow rate of the fluid F flowing through the bypass channel 8 individually. According to the present embodiment, the valve device 9 includes a three-way valve disposed at the second portion 7. The valve device 9 includes a first inflow port 9A connected to the cooler 3, a second inflow port 9B connected to the first portion 6, and an outflow port 9C.

According to the present embodiment, the outflow port 9C includes the second portion 7. That is, the second portion 7 is defined in the outflow port 9C.

The fluid F flowing out of the cooler 3 flows into the valve device 9 from the first inflow port 9A. The fluid F flowing out of the bypass channel 8 flows into the valve device 9 from the second inflow port 9B. The fluid F flowing into the valve device 9 flows out from the outflow port 9C. The fluid F flowing out from the outflow port 9C is fed to the temperature control target 100 through the downstream portion 5C.

The valve device 9 is capable of controlling an opening degree of the first inflow port 9A and an opening degree of the second inflow port 9B individually. When the opening degree of the first inflow port 9A and the opening degree of the second inflow port 9B are individually controlled, the flow rate of the fluid F flowing into the valve device 9 from the first inflow port 9A and the flow rate of the fluid F flowing into the valve device 9 from the second inflow port 9B are controlled.

In the following description, a ratio between the flow rate of the fluid F flowing into the valve device 9 from the first inflow port 9A and the flow rate of the fluid F flowing into the valve device 9 from the second inflow port 9B is referred to as a flow rate ratio as needed.

The opening degree of the first inflow port 9A and the opening degree of the second inflow port 9B are controlled such that the sum of the opening degree of the first inflow port 9A and the opening degree of the second inflow port 9B becomes equal to 100%. For example, when the opening degree of the first inflow port 9A is controlled to be equal to 50%, the opening degree of the second inflow port 9B is controlled to be equal to 50%. When the opening degree of the first inflow port 9A is controlled to be equal to 100%, the opening degree of the second inflow port 9B is controlled to be equal to 0%. When the opening degree of the first inflow port 9A is controlled to be equal to 0%, the opening degree of the second inflow port 9B is controlled to be equal to 100%.

When the opening degree of the first inflow port 9A is controlled to be equal to 100% and the opening degree of the second inflow port 9B is controlled to be equal to 0%, the fluid F fed to the first portion 6 flows through the cooler 3 without flowing through the bypass channel 8. The fluid F flowing through the cooler 3 is cooled. The fluid F flowing out of the cooler 3 flows into the valve device 9 from the first inflow port 9A.

When the opening degree of the second inflow port 9B is controlled to be equal to 100% and the opening degree of the first inflow port 9A is controlled to be equal to 0%, the fluid F fed to the first portion 6 flows through the bypass channel 8 without flowing through the cooler 3. The fluid F flowing through the bypass channel 8 is not temperature-controlled. The fluid F flowing out of the bypass channel 8 flows into the valve device 9 from the second inflow port 9B.

When both the first inflow port 9A and the second inflow port 9B are opened, some of the fluid F fed to the first portion 6 flows through the cooler 3, and the rest of the fluid F fed to the first portion 6 flows through the bypass channel 8. The fluid F flowing out of the cooler 3 flows into the valve device 9 from the first inflow port 9A, and the fluid F flowing out of the bypass channel 8 flows into the valve device 9 from the second inflow port 9B.

The temperature of the fluid F flowing out from the outflow port 9C is controlled through the control of the flow rate ratio. Specifically, the temperature of the fluid F at the second portion 7 is controlled through the control of the flow rate ratio. For example, the fluid F at the second portion 7 when the flow rate ratio is controlled such that the fluid F flowing into the valve device 9 from the first inflow port 9A is higher in flow rate than the fluid F flowing into the valve device 9 from the second inflow port 9B is lower in temperature than the fluid F at the second portion 7 when the flow rate ratio is controlled such that the fluid F flowing into the valve device 9 from the first inflow port 9A is lower in flow rate than the fluid F flowing into the valve device 9 from the second inflow port 9B.

The tank 4 is disposed in the circulation channel 5 between the temperature control target 100 and the first portion 6. The first portion 6 and the second portion 7 are disposed in the circulation channel 5 between the tank 4 and the temperature control target 100.

The fluid F flowing out from the outlet 102 of the temperature control target 100 flows through the upstream portion 5A and then flows through the heater 2 disposed in the tank 4. The fluid F flowing out of the heater 2 is fed to the first portion 6 through at least a part of the midstream portion 5B. The fluid F fed to the first portion 6 flows through the first portion 6 and at least either the cooler 3 or the bypass channel 8, and then reaches the second portion 7 defined in the outflow port 9C of the valve device 9. The fluid F fed to the second portion 7 flows through the second portion 7 and the downstream portion 5C, and then flows into the temperature control target 100.

The control device 10 includes a computer system. As illustrated in FIG. 2, the control device 10 includes a valve controller 11, a heating controller 12, a pump controller 13, and a cooling controller 14.

The valve controller 11 outputs a control signal for controlling the valve device 9. The valve controller 11 controls the opening degree of the first inflow port 9A and the opening degree of the second inflow port 9B individually. The valve controller 11 controls the flow rate ratio through the control of the valve device 9 to make the temperature of the fluid F at the second portion 7 equal to a predetermined temperature. According to the present embodiment, the predetermined temperature includes the target temperature Tr of the temperature control target 100. The valve controller 11 controls the valve device 9 to make the temperature of the fluid F at the second portion 7 equal to the target temperature Tr.

Note that, according to the present embodiment, the predetermined temperature is the target temperature Tr of the temperature control target 100, but may be a set temperature for making the temperature control target 100 equal in temperature to the target temperature Tr. For example, heat dissipation may make the fluid F at the temperature control target 100 lower in temperature than the fluid F at the second portion 7 or the fluid F at the inlet temperature sensor 22. Therefore, the predetermined temperature may be a set temperature set higher than the target temperature Tr of the temperature control target 100. That is, the predetermined temperature may be set slightly higher than the target temperature Tr of the temperature control target 100 with consideration given to a decrease in temperature of the fluid F due to heat dissipation. The predetermined temperature may be set without depending on the temperature control target 100, or may be set based on a command output from the temperature control target 100.

The valve controller 11 controls the valve device 9 based on the detection data of the inlet temperature sensor 22. The valve controller 11 controls, based on the detection data of the inlet temperature sensor 22, the opening degree of the first inflow port 9A and the opening degree of the second inflow port 9B individually to make the temperature of the fluid F at the second portion 7 equal to the target temperature Tr. The fluid F at the second portion 7, the fluid F flowing through the downstream portion 5C, and the fluid F flowing into the inlet 101 are equal in temperature to each other. The inlet temperature sensor 22 can detect the temperature of the fluid F at the second portion 7 and the temperature of the fluid F flowing into the inlet 101 by detecting the temperature of the fluid F flowing through the downstream portion 5C. The valve controller 11 controls the valve device 9 to make the temperature of the fluid F at the second portion 7 equal to the target temperature Tr, thereby allowing the temperature of the fluid F flowing into the inlet 101 to be equal to the target temperature Tr.

The heating controller 12 outputs a control signal for controlling the heater 2. The heating controller 12 controls the heater 2 to prevent the fluid F from being heated when the temperature of the fluid F flowing out of the circulation pump 24 is equal to the first temperature Top higher than the target temperature Tr. The heating controller 12 controls the heater 2 to heat the fluid F when the temperature of the fluid F flowing out of the circulation pump 24 is equal to the second temperature Toa lower than the target temperature Tr. That is, the heating controller 12 stops controlling the heater 2 when the tank temperature Tt is equal to the first temperature Top. When the control of the heater 2 is stopped, the fluid F is not heated. The heating controller 12 starts to control the heater 2 when the tank temperature Tt is equal to the second temperature Toa. When the control of the heater 2 is started, the fluid F is heated.

The heating controller 12 controls the heater 2 to make the temperature of the fluid F equal to a third temperature Th higher than the target temperature Tr when the temperature of the fluid F flowing out of the circulation pump 24 is equal to the second temperature Toa. That is, the heating controller 12 starts to control the heater 2 to make the temperature of the fluid F equal to the third temperature Th when the tank temperature Tt is equal to the second temperature Toa. When the control of the heater 2 is started, the fluid F is heated to make the temperature of the fluid F equal to the third temperature Th.

A difference between the target temperature Tr and the third temperature Th is smaller than a difference between the target temperature Tr and the first temperature Top. As an example, when the target temperature Tr is 80° C., and the first temperature Top is about 90° C., the third temperature Th is about 81° C.

The heating controller 12 controls the heater 2 based on the detection data of tank temperature sensor 25. The heating controller 12 controls, based on the detection data of the tank temperature sensor 25, the heater 2 to make the temperature of the fluid F in the tank 4 equal to the third temperature Th. When determining that the temperature of the fluid F flowing out of the circulation pump 24 is equal to the first temperature Top higher than the target temperature Tr based on the detection data of the tank temperature sensor 25, the heating controller 12 stops controlling the heater 2. When determining that the temperature of the fluid F flowing out of the circulation pump 24 is equal to the second temperature Toa lower than the target temperature Tr based on the detection data of the tank temperature sensor 25, the heating controller 12 starts to control the heater 2.

During the process time, the outlet temperature To of the fluid F flowing out from the outlet 102 is equal to the first temperature Top higher than the target temperature Tr. During the idle time, the outlet temperature To of the fluid F flowing out from the outlet 102 is equal to the second temperature Toa lower than the target temperature Tr. When determining that the tank temperature Tt is equal to the first temperature Top based on the detection data of the tank temperature sensor 25, the heating controller 12 stops controlling the heater 2. When determining that the tank temperature Tt is equal to the second temperature Toa based on the detection data of the tank temperature sensor 25, the heating controller 12 starts to control the heater 2 to make the temperature of the fluid F equal to the third temperature Th.

The valve controller 11 controls the valve device 9 to cause the fluid F flowing out of the heater 2 to flow through the cooler 3. During the process time, the control of the heater 2 is stopped, and the temperature of the fluid F in the tank 4 is equal to the first temperature Top. During the idle time, the control of the heater 2 is active, and the temperature of the fluid F in the tank 4 is equal to the third temperature Th. According to the present embodiment, the temperature of the fluid F fed to the first portion 6 is higher than the target temperature Tr during both the process time and the idle time. The valve controller 11 controls the valve device 9 to cause at least some of the fluid F fed to the first portion 6 to flow through the cooler 3. When at least some of the fluid F fed to the first portion 6 flows through the cooler 3, the temperature of the fluid F at the second portion 7 is made equal to the target temperature Tr.

The pump controller 13 outputs a control signal for controlling the circulation pump 24. The pump controller 13 controls, based on the detection data of the flow rate sensor 23, the circulation pump 24 to make the flow rate of the fluid F circulating through the circulation channel 5 constant.

The cooling controller 14 outputs a control signal for controlling the cooler 3. The cooling controller 14 controls the flow rate control valve 32 to control the flow rate of the cooling fluid C to be fed to the heat exchanger 30. When the flow rate of the cooling fluid C to be fed to the heat exchanger 30 is changed, the cooling capacity of the fluid F used by the heat exchanger 30 is changed.

<Control Method>

Next, a description will be given of a temperature control method applied to the temperature control target 100 according to the present embodiment. FIG. 3 is a flowchart illustrating the temperature control method according to the present embodiment.

With the fluid F stored in the tank 4, the pump controller 13 drives the circulation pump 24. When the circulation pump 24 is driven, the fluid F circulates through the circulation channel 5. The heating controller 12 starts to control the heater 2 to heat the fluid F so as to make the temperature of the fluid F equal to the target temperature Tr. The cooling controller 14 places the cooler 3 into operation. According to the present embodiment, it is assumed that the cooling capacity of the cooler 3 is constant.

After the fluid F made equal in temperature to the target temperature Tr is fed to the temperature control target 100, a semiconductor wafer is loaded into the temperature control target 100, and plasma treatment is applied. Further, after the plasma treatment is completed, the semiconductor wafer is unloaded from the temperature control target 100. During the process time that the plasma treatment is applied, the temperature control target 100 is heated to make the outlet temperature To of the fluid F equal to the first temperature Top higher than the target temperature Tr. During the idle time that the plasma treatment is not applied, the temperature control target 100 is not heated to make the outlet temperature To of the fluid F equal to the second temperature Toa lower than the target temperature Tr.

The tank temperature sensor 25 detects the tank temperature Tt of the fluid F. The heating controller 12 determines whether or not the tank temperature Tt is lower than the target temperature Tr (Step SA1).

When determining in Step SA1 that the tank temperature Tt is lower than the target temperature Tr (Step SA1: Yes), the heating controller 12 starts to control the heater 2 to make the temperature of the fluid F equal to the third temperature Th (Step SA2).

The fluid F in the tank 4 made equal in temperature to the third temperature Th is fed from the tank 4 to the first portion 6 of the circulation channel 5.

The valve controller 11 controls the valve device 9 to make the temperature of the fluid F at the second portion 7 equal to the target temperature Tr (Step SA3).

The valve controller 11 controls the flow rate ratio through the individual control of the opening degree of the first inflow port 9A and the opening degree of the second inflow port 9B to make the temperature of the fluid F at the second portion 7 equal to the target temperature Tr. The valve controller 11 feedback-controls, based on the detection data of the inlet temperature sensor 22, the valve device 9 to make the temperature of the fluid F at the second portion 7 equal to the target temperature Tr.

The valve controller 11 controls the valve device 9 to feed at least some of the fluid F fed to the first portion 6 to the cooler 3. The fluid F fed to the cooler 3 is cooled.

The fluid F flowing out of the cooler 3 flows into the valve device 9 from the first inflow port 9A. The fluid F flowing out of the bypass channel 8 flows into the valve device 9 from the second inflow port 9B. The fluid F flowing out of the cooler 3 and the fluid F flowing out of the bypass channel 8 are mixed in the valve device 9. The fluid F mixed in the valve device 9 flows out from the outflow port 9C. The temperature of the fluid F flowing out from the outflow port 9C is made equal to the target temperature Tr. That is, the temperature of the fluid F at the second portion 7 is made equal to the target temperature Tr.

When the temperature of the fluid F at the second portion 7 is made equal to the target temperature Tr, the fluid F made equal in temperature to the target temperature Tr is fed to the temperature control target 100.

When determining in Step SA1 that the tank temperature Tt is higher than the target temperature Tr (Step SA1: No), the heating controller 12 stops controlling the heater 2 (Step SA4).

The temperature of the fluid F stored in the tank 4 is equal to the first temperature Top. The fluid F stored in the tank 4 is fed from the tank 4 to the first portion 6 of the circulation channel 5.

The valve controller 11 controls the valve device 9 to make the temperature of the fluid F at the second portion 7 equal to the target temperature Tr (Step SA3).

The valve controller 11 controls the valve device 9 to feed at least some of the fluid F fed to the first portion 6 to the cooler 3. The fluid F fed to the cooler 3 is cooled.

The fluid F flowing out of the cooler 3 flows into the valve device 9 from the first inflow port 9A. The fluid F flowing out of the bypass channel 8 flows into the valve device 9 from the second inflow port 9B. The fluid F flowing out of the cooler 3 and the fluid F flowing out of the bypass channel 8 are mixed in the valve device 9. The fluid F mixed in the valve device 9 flows out from the outflow port 9C. The temperature of the fluid F flowing out from the outflow port 9C is made equal to the target temperature Tr. That is, the temperature of the fluid F at the second portion 7 is made equal to the target temperature Tr.

When the temperature of the fluid F at the second portion 7 is made equal to the target temperature Tr, the fluid F made equal in temperature to the target temperature Tr is fed to the temperature control target 100.

<Effects>

As described above, according to the present embodiment, provided are the circulation channel 5 including the temperature control target 100, the heater 2, and the cooler 3, the bypass channel 8 that bypasses the cooler 3, and the valve device 9 capable of controlling the flow rate of the fluid F flowing through the cooler 3 and the flow rate of the fluid F flowing through the bypass channel 8 individually. The valve controller 11 controls the valve device 9 to make the temperature of the fluid F at the second portion 7 equal to the predetermined temperature. Since the flow rate ratio is controlled through the control of the valve device 9, the temperature of the fluid F at the second portion 7 can be made equal to the target temperature Tr without, for example, continuous control of the heater 2 or excessive increase in the cooling capacity of the cooler 3. This reduces energy consumed by the heater 2 and energy consumed by the cooler 3 during the temperature-control of the temperature control target 100.

The heating controller 12 stops controlling the heater 2 to prevent the fluid F from being heated when the temperature of the fluid F flowing out of the circulation pump 24 is equal to the first temperature Top higher than the target temperature Tr, and starts to control the heater 2 to heat the fluid F when the temperature of the fluid F flowing out of the circulation pump 24 is equal to the second temperature Toa lower than the target temperature Tr. Since the heater 2 is stopped when the temperature of the fluid F flowing out of the circulation pump 24 is equal to the first temperature Top higher than the target temperature Tr, the energy consumed by the heater 2 is reduced.

The heating controller 12 starts to control the heater 2 to make the temperature of the fluid F equal to the third temperature Th higher than the target temperature Tr when the temperature of the fluid F flowing out of the circulation pump 24 is equal to the second temperature Toa. The difference between the target temperature Tr and the third temperature Th is smaller than the difference between the target temperature Tr and the first temperature Top. Therefore, when the temperature of the fluid F flowing out of the circulation pump 24 is equal to the second temperature Toa lower than the target temperature Tr, the fluid F is heated to the third temperature Th with less energy consumed by the heater 2.

The valve controller 11 controls the valve device 9 to cause the fluid F flowing out of the heater 2 to flow through the cooler 3. According to the present embodiment, the fluid F having the first temperature Top or the fluid F having the third temperature Th is fed to the first portion 6. That is, the fluid F having a temperature higher than the target temperature Tr is fed to the first portion 6. Since at least some of the fluid F fed to the first portion 6 and having a temperature higher than the target temperature Tr is cooled by the cooler 3, the valve controller 11 can control the temperature of the fluid F at the second portion 7 with high robustness.

The heating controller 12 controls the heater 2 based on the detection data of tank temperature sensor 25. When determining that the tank temperature Tt is equal to the first temperature Top based on the detection data of the tank temperature sensor 25, the heating controller 12 can stop controlling the heater 2. When determining that the tank temperature Tt is equal to the second temperature Toa based on the detection data of the tank temperature sensor 25, the heating controller 12 can place the heater 2 into operation with less consumed energy to make the temperature of the fluid F equal to the third temperature Th. As a result, the energy consumed by the heater 2 is reduced.

The heater 2 is disposed in the tank 4 and heats the fluid F stored in the tank 4. The fluid F stored in the tank 4 is circulated by convection or mixed, thereby making the temperature of the fluid F uniform in the tank 4. Since the fluid F having a uniform temperature is fed from the tank 4 to the first portion 6, the temperature of the fluid F at the second portion 7 is controlled with high accuracy.

The first portion 6 and the second portion 7 are defined between the tank 4 and the temperature control target 100 on the downstream side of the tank 4. The cooler 3 is disposed outside the tank 4. Disposing the cooler 3 outside the tank 4 allows the tank 4 to be downsized. Downsizing the tank 4 allows the temperature control system 1A to be downsized and suppresses an increase in cost.

<Other Embodiment>

Note that, according to the above-described embodiment, the valve controller 11 feedback-controls, based on the detection data of the inlet temperature sensor 22, the valve device 9 to make the temperature of the fluid F at the second portion 7 equal to the target temperature Tr. The valve controller 11 may feedforward-control the valve device 9 based on the detection data of the tank temperature sensor 25, or may feedback-control and feedforward-control the valve device 9 based on the detection data of the inlet temperature sensor 22 and the detection data of the tank temperature sensor 25.

Likewise, the heating controller 12 may feedforward-control the heater 2 based on the detection data of the outlet temperature sensor 21, or may feedback-control and feedforward-control the heater 2 based on the detection data of the tank temperature sensor 25 and the detection data of the outlet temperature sensor 21.

Note that, according to the above-described embodiment, the heating controller 12 controls the heater 2 based on the detection data of the tank temperature sensor 25. The heating controller 12 may receive, for example, recipe data indicating whether or not it is in the process time from the plasma treatment apparatus. The heating controller 12 may stop the heater 2 when determining that it is in the process time based on the recipe data and start to control the heater 2 when determining that it is the idle time.

### Second Embodiment

A description will be given of a second embodiment. In the following description, the same or equivalent components as the components of the above-described embodiment will be denoted by the same reference numerals, and will be described in a simplified manner or will not be described at all.

<Temperature Control System>

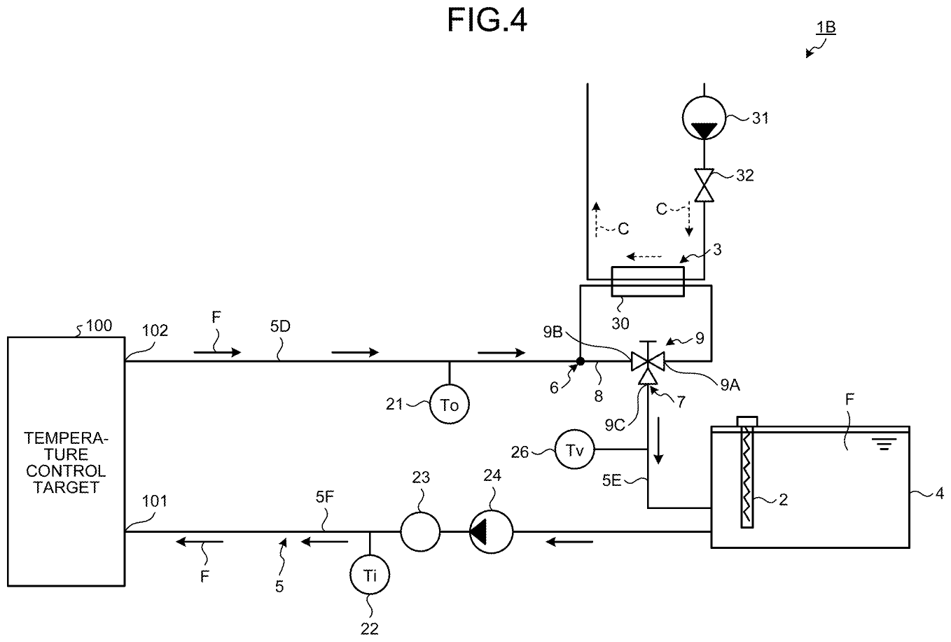

FIG. 4 is a diagram illustrating a structure of a temperature control system 1B according to the present embodiment. As illustrated in FIG. 4, the temperature control system 1B includes a circulation channel 5 including a temperature control target 100 to be temperature-controlled via a fluid F, a heater 2 capable of heating the fluid F, a cooler 3 capable of cooling the fluid F, and a tank 4, a bypass channel 8 connected to a first portion 6 of the circulation channel 5 located upstream of the cooler 3 and a second portion 7 of the circulation channel 5 located downstream of the cooler 3 to bypass the cooler 3, a valve device 9 capable of controlling a flow rate of the fluid F flowing through the cooler 3 and a flow rate of the fluid F flowing through the bypass channel 8 individually, and a control device 10. Note that the control device 10 is not illustrated in FIG. 4. The control device 10 is similar in structure to the control device 10 described with reference to FIG. 2.

The temperature control system 1B further includes an outlet temperature sensor 21 configured to detect an outlet temperature To indicating the temperature of the fluid F flowing out of the temperature control target 100, an inlet temperature sensor 22 configured to detect an inlet temperature Ti indicating the temperature of the fluid F flowing into the temperature control target 100, a valve temperature sensor 26 configured to detect a valve temperature Tv indicating the temperature of the fluid F flowing out of the valve device 9, a flow rate sensor 23 configured to detect a flow rate of the fluid F flowing through the circulation channel 5, and a circulation pump 24 configured to be driven to cause the fluid F to circulate through the circulation channel 5.

The heater 2 heats the fluid F. The heater 2 is disposed in the tank 4. The heater 2 heats the fluid F stored in the tank 4.

The cooler 3 cools the fluid F. The cooler 3 includes a heat exchanger 30, a feed pump 31 configured to be driven to feed a cooling fluid C to the heat exchanger 30, and a flow rate control valve 32 configured to control a flow rate of the cooling fluid C to be fed to the heat exchanger 30.

The circulation channel 5 includes an upstream portion 5D extending between an outlet 102 and the cooler 3, a midstream portion 5E extending between the cooler 3 and the tank 4, and a downstream portion 5F extending between the tank 4 and the inlet 101. The circulation pump 24 is disposed in the downstream portion 5F. When the circulation pump 24 is driven, the fluid F circulates through the circulation channel 5.

The outlet temperature sensor 21 detects the temperature of the fluid F flowing out from the outlet 102. The outlet temperature sensor 21 is provided in the upstream portion 5D of the circulation channel 5.

The inlet temperature sensor 22 detects the temperature of the fluid F flowing into the inlet 101. The inlet temperature sensor 22 is provided in the downstream portion 5F of the circulation channel 5. The inlet temperature sensor 22 detects the temperature of the fluid F that has been cooled by the cooler 3 and heated by the heater 2.

The valve temperature sensor 26 detects the temperature of the fluid F flowing out of the temperature control target 100 and flowing out of the valve device 9. The valve temperature sensor 26 is provided in the midstream portion 5E of the circulation channel 5 between the outflow port 9C of the valve device 9 and the tank 4. The valve temperature sensor 26 detects the temperature of the fluid F flowing through the midstream portion 5E. The valve temperature sensor 26 detects the temperature of the fluid F that has been cooled by the cooler 3, but has not yet been heated by the heater 2. Detection data of the valve temperature sensor 26 is output to the control device 10.

The flow rate sensor 23 detects the flow rate of the fluid F flowing through the circulation channel 5. The flow rate sensor 23 is provided in the downstream portion 5F of the circulation channel 5.

The bypass channel 8 is provided to bypass the cooler 3. The bypass channel 8 is provided to connect the first portion 6 of the circulation channel 5 and the second portion 7 of the circulation channel 5. The first portion 6 is defined in the upstream portion 5D of the circulation channel 5. The second portion 7 is defined in the midstream portion 5E of the circulation channel 5.

The first portion 6 is defined in the upstream portion 5D between the outlet temperature sensor 21 and the cooler 3. The second portion 7 is defined in the midstream portion 5E between the cooler 3 and the tank 4.

The valve device 9 controls the flow rate of the fluid F flowing through the cooler 3 and the flow rate of the fluid F flowing through the bypass channel 8 individually. The valve device 9 includes a three-way valve disposed at the second portion 7. The valve device 9 includes a first inflow port 9A connected to the cooler 3, a second inflow port 9B connected to the first portion 6, and an outflow port 9C including the second portion 7.

When a flow rate ratio indicating a ratio between the flow rate of the fluid F flowing into the valve device 9 from the first inflow port 9A and the flow rate of the fluid F flowing into the valve device 9 from the second inflow port 9B is controlled, the temperature of the fluid F flowing out from the outflow port 9C is controlled. The temperature of the fluid F at the second portion 7 is controlled through the control of the flow rate ratio.

The tank 4 is disposed in the circulation channel 5 between the second portion 7 and the temperature control target 100. The first portion 6 and the second portion 7 are disposed in the circulation channel 5 between the temperature control target 100 and the tank 4.

The fluid F flowing out from the outlet 102 of the temperature control target 100 flows through the upstream portion 5D and then reaches the first portion 6. The fluid F fed to the first portion 6 flows through the first portion 6 and at least either the cooler 3 or the bypass channel 8, and then reaches the second portion 7 defined in the outflow port 9C of the valve device 9. The fluid F fed to the second portion 7 flows through the second portion 7 and is then fed to the tank 4 through at least a part of the midstream portion 5E. The fluid F fed to the tank 4 flows through the heater 2 disposed in the tank 4. The fluid F flowing out of the heater 2 flows through the downstream portion 5F and then flows into the temperature control target 100.

The control device 10 includes a computer system. As illustrated in FIG. 2, the control device 10 includes a valve controller 11, a heating controller 12, a pump controller 13, and a cooling controller 14.

The valve controller 11 outputs a control signal for controlling the valve device 9. The valve controller 11 controls an opening degree of the first inflow port 9A and an opening degree of the second inflow port 9B. The valve controller 11 controls the valve device 9 to make the temperature of the fluid F at the second portion 7 equal to the predetermined temperature. According to the present embodiment, the predetermined temperature includes a fourth temperature Tl lower than the target temperature Tr of the temperature control target 100. The valve controller 11 controls the valve device 9 to make the temperature of the fluid F at the second portion 7 equal to the fourth temperature Tl.

A difference between the target temperature Tr and the fourth temperature Tl is equal to a difference between the target temperature Tr and the second temperature Toa. Note that the difference between the target temperature Tr and the fourth temperature Tl may be larger or smaller than the difference between the target temperature Tr and the second temperature Toa. As an example, when the target temperature Tr is 80° C., the fourth temperature Tl is about 79° C.

The valve controller 11 controls the valve device 9 based on the detection data of the valve temperature sensor 26. The valve controller 11 controls, based on the detection data of the valve temperature sensor 26, the opening degree of the first inflow port 9A and the opening degree of the second inflow port 9B to make the temperature of the fluid F at the second portion 7 equal to the fourth temperature Tl.

As in the above-described embodiment, during the process time, the temperature of the fluid F flowing out from the outlet 102 is equal to the first temperature Top higher than the target temperature Tr. During the idle time, the temperature of the fluid F flowing out from the outlet 102 is equal to the second temperature Toa lower than the target temperature Tr.

The valve controller 11 controls the valve device 9 to cause the fluid F to flow through the cooler 3 when the temperature of the fluid F flowing out of the valve device 9 is equal to the first temperature Top higher than the target temperature Tr, and controls the valve device 9 to cause the fluid F to flow through the bypass channel 8 when the temperature of the fluid F flowing out of the valve device 9 is equal to the second temperature Toa lower than the target temperature Tr.

When determining that the temperature of the fluid F flowing out from the outflow port 9C of the valve device 9 is equal to the first temperature Top based on the detection data of the valve temperature sensor 26, the valve controller 11 controls the valve device 9 to make the temperature of the fluid F at the second portion 7 equal to the fourth temperature Tl. When determining that the temperature of the fluid F flowing out from the outflow port 9C of the valve device 9 is equal to the first temperature Top, the valve controller 11 controls the valve device 9 to feed, to the cooler 3, at least some of the fluid F fed to the first portion 6.

When determining that the temperature of the fluid F flowing out from the outflow port 9C of the valve device 9 is equal to the second temperature Toa based on the detection data of the valve temperature sensor 26, the valve controller 11 controls the valve device 9 to make the temperature of the fluid F at the second portion 7 equal to the fourth temperature Tl.

Note that, when determining that the temperature of the fluid F flowing out from the outflow port 9C of the valve device 9 is equal to the second temperature Toa, the valve controller 11 may control the valve device 9 to cause all the fluid F fed to the first portion 6 to flow through the bypass channel 8 and prevent the fluid F fed to the first portion 6 from flowing through the cooler 3 so as to make the temperature of the fluid F at the second portion 7 equal to the second temperature Toa.

According to the present embodiment, during both the process time and the idle time, the temperature of the fluid F to be fed to the heater 2 through the second portion 7 is equal to the second temperature Toa or the fourth temperature Tl that are lower than the target temperature Tr.

The heating controller 12 outputs a control signal for controlling the heater 2. The heating controller 12 controls the heater 2 to make the temperature of the fluid F equal to the target temperature Tr. According to the present embodiment, the heating controller 12 controls, based on the detection data of the inlet temperature sensor 22, the heater 2 to make the temperature of the fluid F flowing into the inlet 101 equal to the target temperature Tr.

<Control Method>

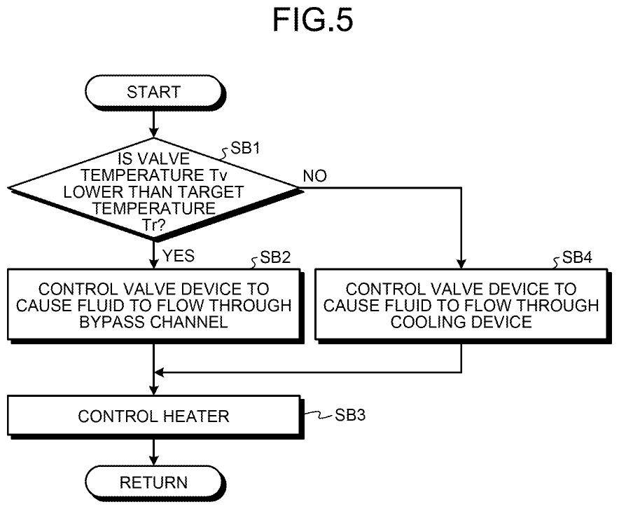

Next, a description will be given of a temperature control method applied to the temperature control target 100 according to the present embodiment. FIG. 5 is a flowchart illustrating a temperature control method according to the present embodiment.

With the fluid F stored in the tank 4, the pump controller 13 drives the circulation pump 24. When the circulation pump 24 is driven, the fluid F circulates through the circulation channel 5. The heating controller 12 starts to control the heater 2 to heat the fluid F so as to make the temperature of the fluid F equal to the target temperature Tr. The cooling controller 14 places the cooler 3 into operation. According to the present embodiment, it is assumed that the cooling capacity of the cooler 3 is constant.

After the fluid F made equal in temperature to the target temperature Tr is fed to the temperature control target 100, a semiconductor wafer is loaded into the temperature control target 100, and plasma treatment is applied. During the process time that the temperature control target 100 is heated, the outlet temperature To of the fluid F flowing out from the outlet 102 is equal to the first temperature Top higher than the target temperature Tr. During the idle time that the temperature control target 100 is not heated, the outlet temperature To of the fluid F flowing out from the outlet 102 is equal to the second temperature Toa lower than the target temperature Tr.

The valve temperature sensor 26 detects the valve temperature Tv of the fluid F flowing out from the outflow port 9C of the valve device 9. The valve controller 11 determines whether or not the valve temperature Tv is lower than the target temperature Tr (Step SB1).

In Step SB1, when determining that the valve temperature Tv is equal to the second temperature Toa lower than the target temperature Tr (Step SB1: Yes), the valve controller 11 controls the valve device 9 to cause the fluid F fed to the first portion 6 to flow through the bypass channel 8 (Step SB2).

According to the present embodiment, the valve controller 11 controls the valve device 9 to cause all the fluid F fed to the first portion 6 to flow through the bypass channel 8 and prevent the fluid F from flowing through the cooler 3. As a result, the fluid F having the second temperature Toa lower than the target temperature Tr is fed to the second portion 7 through the bypass channel 8.

Note that, when determining that the valve temperature Tv is equal to the second temperature Toa, the valve controller 11 may control the opening degree of the first inflow port 9A and the opening degree of the second inflow port 9B to cause some of the fluid F fed to the first portion 6 to flow through the cooler 3 and cause the rest of the fluid F fed to the first portion 6 to flow through the bypass channel 8 so as to make the temperature of the fluid F at the second portion 7 equal to the fourth temperature Tl.

The fluid F flowing out from the outflow port 9C is fed to the tank 4. The heating controller 12 controls the heater 2 to make the temperature of the fluid F fed to the tank 4 equal to the target temperature Tr (Step SB3).

The heating controller 12 feedback-controls, based on the detection data of the inlet temperature sensor 22, the heater 2 to make the temperature of the fluid F to be fed to the temperature control target 100 equal to the target temperature Tr.

When the control of the heater 2 is started, the temperature of the fluid F in the tank 4 is made equal to the target temperature Tr. The fluid F made equal to the target temperature Tr is fed from the tank 4 to the temperature control target 100 through the downstream portion 5F.

In Step SB1, when determining that the valve temperature Tv is higher than the target temperature Tr (Step SB1: No), the valve controller 11 controls the valve device 9 to cause the fluid F fed to the first portion 6 to flow through the cooler 3 (Step SB3).

According to the present embodiment, the valve controller 11 controls the valve device 9 to cause all the fluid F fed to the first portion 6 to flow through the cooler 3 and prevent the fluid F from flowing through the bypass channel 8. Note that the valve controller 11 may control the valve device 9 to cause some of the fluid F fed to the first portion 6 to flow through the cooler 3 and cause the rest of the fluid F fed to the first portion 6 to flow through the bypass channel 8. As a result, the fluid F having the fourth temperature Tl lower than the target temperature Tr is fed to the second portion 7.

The fluid F flowing out from the outflow port 9C is fed to the tank 4. The heating controller 12 controls the heater 2 to make the temperature of the fluid F fed to the tank 4 equal to the target temperature Tr (Step SB3).

When the control of the heater 2 is started, the temperature of the fluid F in the tank 4 is made equal to the target temperature Tr. The fluid F made equal to the target temperature Tr is fed from the tank 4 to the temperature control target 100 through the downstream portion 5F.

<Effects>

As described above, according to the present embodiment, provided are the circulation channel 5 including the temperature control target 100, the heater 2, and the cooler 3, the bypass channel 8 that bypasses the cooler 3, and the valve device 9 capable of controlling the flow rate of the fluid F flowing through the cooler 3 and the flow rate of the fluid F flowing through the bypass channel 8 individually. The valve controller 11 controls the valve device 9 to make the temperature of the fluid F at the second portion 7 equal to the predetermined temperature. Since the flow rate ratio is controlled through the control of the valve device 9, the temperature of the fluid F at the second portion 7 can be made equal to the fourth temperature Tl without, for example, continuous control of the heater 2 or excessive increase in the cooling capacity of the cooler 3. This allows a reduction in energy consumed by the heater 2 and energy consumed by the cooler 3 during the temperature-control of the temperature control target 100.

The valve controller 11 controls the valve device 9 to cause the fluid F to flow through the cooler 3 when the temperature of the fluid F flowing out of the valve device 9 is equal to the first temperature Top higher than the target temperature Tr, and controls the valve device 9 to cause the fluid F to flow through the bypass channel 8 when the temperature of the fluid F flowing out of the valve device 9 is equal to the second temperature Toa lower than the target temperature Tr. When the temperature of the fluid F flowing out of the valve device 9 is equal to the second temperature Toa lower than the target temperature Tr, cooling by the cooler 3 is not applied, so that energy consumed by the cooler 3 is reduced.

The valve controller 11 controls the valve device 9 based on the detection data of the valve temperature sensor 26. When determining that the valve temperature Tv is equal to the second temperature Toa based on the detection data of the valve temperature sensor 26, the valve controller 11 controls the valve device 9 to prevent the fluid F from flowing through the cooler 3 and cause the fluid F to flow through the bypass channel 8. When determining that the valve temperature Tv is equal to the first temperature Top based on the detection data of the valve temperature sensor 26, the valve controller 11 controls the valve device 9 to cause the fluid F to flow through the cooler 3. The valve controller 11 can make the temperature of the fluid F fed to the second portion 7 lower than the target temperature Tr with less energy consumed by the cooler 3.

The heater 2 is disposed in the tank 4 and heats the fluid F stored in the tank 4. The fluid F stored in the tank 4 is circulated by convection or mixed, thereby making the temperature of the fluid F stored in the tank 4 uniform. Since the fluid F having a uniform temperature is fed from the tank 4 to the temperature control target 100, the temperature control target 100 is suitably temperature-controlled.

The first portion 6 and the second portion 7 are defined between the temperature control target 100 and the tank 4 on the upstream side of the tank 4. The cooler 3 is disposed outside the tank 4. This allows the tank 4 to be downsized. This in turn allows the temperature control system 1B to be downsized and suppresses an increase in cost.

<Other Embodiment>

Note that, according to the above-described embodiment, the valve controller 11 feedback-controls, based on the detection data of the valve temperature sensor 26, the valve device 9 to make the temperature of the fluid F at the second portion 7 equal to the target temperature Tr. The valve controller 11 may feedforward-control the valve device 9 based on the detection data of the outlet temperature sensor 21, or may feedback-control and feedforward-control the valve device 9 based on the detection data of the valve temperature sensor 26 and the detection data of the outlet temperature sensor 21.

Likewise, the heating controller 12 may feedforward-control the heater 2 based on the detection data of the valve temperature sensor 26, or may feedback-control and feedforward-control the heater 2 based on the detection data of the inlet temperature sensor 22 and the detection data of the valve temperature sensor 26.

Note that, according to the above-described embodiment, the valve controller 11 controls, based on the detection data of the valve temperature sensor 26, the flow rate of the fluid F flowing through the cooler 3 and the flow rate of the fluid F flowing through the bypass channel 8. The valve controller 11 may receive, for example, recipe data indicating whether or not it is in the process time from the plasma treatment apparatus. The valve controller 11 may control the valve device 9 to cause the fluid F to flow through the cooler 3 when determining that it is in the process time based on the recipe data, and may control the valve device 9 to cause the fluid F to flow through the bypass channel 8 when determining that it is in the idle time based on the recipe data.

### REFERENCE SIGNS LIST

1A TEMPERATURE CONTROL SYSTEM
1B TEMPERATURE CONTROL SYSTEM
2 HEATER
3 COOLER
4 TANK
5 CIRCULATION CHANNEL
5A UPSTREAM PORTION
5B MIDSTREAM PORTION
5C DOWNSTREAM PORTION
5D UPSTREAM PORTION
5E MIDSTREAM PORTION
5F DOWNSTREAM PORTION
6 FIRST PORTION
7 SECOND PORTION
8 BYPASS CHANNEL
9 VALVE DEVICE
9A FIRST INFLOW PORT
9B SECOND INFLOW PORT
9C OUTFLOW PORT
10 CONTROL DEVICE
11 VALVE CONTROLLER
12 HEATING CONTROLLER
13 PUMP CONTROLLER
14 COOLING CONTROLLER
21 OUTLET TEMPERATURE SENSOR
22 INLET TEMPERATURE SENSOR
23 FLOW RATE SENSOR
24 CIRCULATION PUMP
25 TANK TEMPERATURE SENSOR
26 VALVE TEMPERATURE SENSOR
30 HEAT EXCHANGER
31 FEED PUMP
32 FLOW RATE CONTROL VALVE
100 TEMPERATURE CONTROL TARGET
101 INLET
102 OUTLET
C COOLING FLUID
F FLUID

1. A temperature control system comprising:
a circulation channel including a temperature control target to be temperature-controlled via a fluid, a heater capable of heating the fluid, and a cooler capable of cooling the fluid;
a bypass channel connected to a first portion of the circulation channel located upstream of the cooler and a second portion of the circulation channel located downstream of the cooler to bypass the cooler;
a valve device capable of controlling a flow rate of the fluid flowing through the cooler and a flow rate of the fluid flowing through the bypass channel individually; and
a control device including a valve controller configured to control the valve device to make a temperature of the fluid at the second portion equal to a predetermined temperature.

2. The temperature control system according to claim 1, wherein
the fluid flowing out of the temperature control target flows into the temperature control target after flowing through the heater, the first portion, and the second portion, and
the predetermined temperature includes a target temperature of the temperature control target.

3. The temperature control system according to claim 2, wherein
the control device includes a heating controller configured to control the heater, and
the heating controller controls the heater to prevent the fluid from being heated when the temperature of the fluid flowing out of the temperature control target is equal to a first temperature higher than the target temperature, and controls the heater to heat the fluid when the temperature of the fluid flowing out of the temperature control target is equal to a second temperature lower than the target temperature.

4. The temperature control system according to claim 3, wherein the heating controller controls the heater to make the temperature of the fluid equal to a third temperature higher than the target temperature when the temperature of the fluid flowing out of the temperature control target is equal to the second temperature.

5. The temperature control system according to claim 3, wherein the valve controller controls the valve device to cause the fluid flowing out of the heater to flow through the cooler.

6. The temperature control system according to claim 3, further comprising a tank temperature sensor configured to detect the temperature of the fluid flowing out of the temperature control target,
wherein the heating controller controls the heater based on detection data of the tank temperature sensor.

7. The temperature control system according to claim 2, further comprising an inlet temperature sensor configured to detect the temperature of the fluid flowing into the temperature control target,
wherein the valve controller controls the valve device based on detection data of the inlet temperature sensor.

8. The temperature control system according to claim 2, wherein
the circulation channel includes a tank disposed between the temperature control target and the first portion, and
the heater is disposed in the tank.

9. The temperature control system according to claim 8, wherein the first portion and the second portion are disposed downstream of the tank.

10. The temperature control system according to claim 1, wherein
the fluid flowing out of the temperature control target flows into the temperature control target after flowing through the first portion, the second portion, and the heater and
the predetermined temperature includes a fourth temperature lower than a target temperature of the temperature control target.

11. The temperature control system according to claim 10, wherein
the control device includes a heating controller configured to control the heater, and
the valve controller controls the valve device to cause the fluid to flow through the cooler when the temperature of the fluid flowing out of the temperature control target is equal to a first temperature higher than the target temperature, and controls the valve device to cause the fluid to flow through the bypass channel when the temperature of the fluid flowing out of the temperature control target is equal to a second temperature lower than the target temperature.

12. The temperature control system according to claim 11, wherein the heating controller controls the heater to make the temperature of the fluid equal to the target temperature.

13. The temperature control system according to claim 11, further comprising an inlet temperature sensor configured to detect the temperature of the fluid flowing into the temperature control target,
wherein the heating controller controls the heater based on detection data of the inlet temperature sensor.

14. The temperature control system according to claim 10, further comprising a valve temperature sensor configured to detect the temperature of the fluid flowing out of the temperature control target,
wherein the valve controller controls the valve device based on detection data of the valve temperature sensor.

15. The temperature control system according to claim 10, wherein
the circulation channel includes a tank disposed between the second portion and the temperature control target, and
the heater is disposed in the tank.

16. The temperature control system according to claim 15, wherein the first portion and the second portion are disposed upstream of the tank.

17. The temperature control system according to claim 1, wherein the valve device includes a three-way valve disposed at the second portion.

18. A temperature control method comprising:
causing a fluid to circulate through a circulation channel including a temperature control target to be temperature-controlled via the fluid, a heater capable of heating the fluid, and a cooler capable of cooling the fluid;
causing the fluid to flow through a bypass channel connected to each of a first portion of the circulation channel located upstream of the cooler and a second portion of the circulation channel located downstream of the cooler to bypass the cooler; and
controlling a flow rate of the fluid flowing through the cooler and a flow rate of the fluid flowing through the bypass channel individually to make a temperature of the fluid at the second portion equal to a predetermined temperature.
